(19) United States
(12) Patent Application Publication
(10) Pub. No.: US 2017/0345700 A1
(43) Pub. Date: Nov. 30, 2017

(54) VACUUM CLAMPING DEVICE FOR GRIPPING WORKPIECES

(71) Applicant: mechatronic systemtechnik GmbH, Villach (AT)

(72) Inventor: Alexander Oremus, Villach (AT)

(21) Appl. No.: 15/537,065

(22) PCT Filed: Dec. 17, 2015
(86) PCT No.: PCT/EP2015/080135

§ 371 Date: Jun. 16, 2017

(30) Foreign Application Priority Data
Dec. 17, 2014 (DE) 10 2014 118 830.6

(51) Int. Cl. H01L 21/683; H01L 21/67

(52) U.S. Cl. CPC H01L 21/6838; H01L 21/67288

(57) ABSTRACT

The present invention among other things relates to a vacuum clamping device for clamping of workpieces, in particular for clamping of flat substrates, with a vacuum clamping plate (10), which has a number of suction openings (16) which are distributed over its surface and which are formed in a suction surface (14) of the vacuum clamping plate (10) or which are in connection to a number of suction grooves (15 ) which are formed in the suction surface (14) of the vacuum clamping plate (10), wherein the vacuum clamping plate (10) has two or more vacuum zones (11,12) which are separate from each other and are individually switchable, wherein each vacuum zone (11,12) has corresponding suction openings (16) and/or suction grooves (15) with suction openings (16). In order to further develop the vacuum clamping device in such a way, that with it large holding forces can be generated in a targeted manner, wherein simultaneously damaging of the workpiece to be clamped has to be avoided, it is provided, that the vacuum clamping device has two or more separate vacuum circuits which are independent from each other, that each vacuum zone (11, 12) is assigned to one of the vacuum circuits or is part of one of the vacuum circuits and that each vacuum circuit is designed for generating a self-contained vacuum.

### REFERENCE TO PENDING PRIOR PATENT APPLICATIONS

This patent application claims benefit of International (PCT) Patent Application No. PCT/EP2015/080135, filed 17 Dec. 2015 by mechatronic systemtechnik GmbH for VACUUM CLAMPING DEVICE FOR GRIPPING WORKPIECES, which claims benefit of German Patent Application No. DE 10 2014 118 830.6, filed 17 Dec. 2014, which patent applications are hereby incorporated herein by reference.

### FIELD OF THE INVENTION

The present invention relates to a vacuum clamping device for clamping workpieces, in particular for clamping flat substrates.

### BACKGROUND OF THE INVENTION

Vacuum clamping devices of this type are already known in principle in the prior art. Generally, such vacuum clamping devices have a vacuum clamping plate, which has a number of suction openings which are distributed over the surface of the plate, the suction openings being formed in a suction surface of the vacuum clamping plate or which are connected to a number of suction grooves, which are formed in a suction surface of the vacuum clamping plate. Vacuum clamping devices of the mentioned type are used in various technical fields.

One such technical field is the manufacturing and processing of substrates in the form of wafers. A wafer is basically a circular or rectangular disc, on which electronic components are located. During processing of such wafers these are generally located on or in a processing device, which may have for example a processing table. The processing table has a holding device, on which the wafer is arranged during the processing and onto which the wafer is being or has been sucked, for example by means of vacuum. During the processing operation the wafer is usually subjected to forces, so that there is a need to secure the wafer against sliding.

To this end, it has already become known in the prior art to divide the vacuum clamping plate into two or more vacuum zones which are separate from each other and which are individually switchable, wherein each vacuum zone has respective suction openings and/or suction grooves with suction openings. Such a solution is described in DE 10 2004 016 476 B4. The known solution makes it possible to adapt the size of the vacuum clamping plate to the size of the workpiece to be clamped. Depending on the size of the workpiece a corresponding amount of or correspondingly configured vacuum zones are interconnected to a single vacuum clamping plate. However, in operation of the known solution, only a single vacuum circuit is always available then, which generates or provides a vacuum which is uniform over the entire vacuum clamping device.

In a different context it has already become known in the prior art, to adapt the vacuum clamping plate to specific contours of the workpiece to be clamped. In the DE 20 2013 100 632 U1, for example, an additional vacuum plate is applied, for example laid, onto the vacuum clamping plate, wherein the vacuum plate has a first outer surface and a second outer surface opposite thereto and wherein the vacuum plate has a number of vacuum channels, which extend from the first outer surface to the second outer surface through the vacuum plate. The vacuum plate, which in the known solution is designed as a kind of mat, can snug to the workpiece to the clamped. The vacuum channels are connected to the suction openings in the vacuum clamping plate which is located underneath the vacuum plate, such that the vacuum can be generated or provided at the surface of the workpiece to be clamped.

In particular in the field of processing of wafers using a vacuum clamping device it is very important, that, by means of the vacuum clamping device, large holding forces are provided, wherein in particular damaging of the sensitive wafer is to be avoided.

### SUMMARY OF THE INVENTION

Starting from the mentioned prior art, the object of the present invention is to further develop a known vacuum clamping device in such a way, that large holding forces can be generated in a targeted manner, while at the same time avoiding damaging of the workpiece to be clamped.

The object is achieved according to the invention by a vacuum clamping device with the features according to independent claim 1, the vacuum clamping device with the features according independent claim 5 as well as the vacuum clamping device according to independent claim 8.

Further features and details of the invention can be derived from the dependent claims, the description as well as the drawings. Therein, features and details, which are described in context with one of the aspects of the invention are always fully applicable also in context with the respective other two aspects of the invention, so that with respect to the disclosure of the individual aspects of the invention full reference is always made mutually to the respective other aspects of the invention and reference is made to the corresponding explanations.

The present invention is based on the basic idea that with a vacuum clamping device according to all three aspects of the invention for clamping substrates, in particular for clamping flat substrates, a, in particular targeted, increase of the holding forces can be implemented. For this purpose, according to the present patent application three alternative solutions are provided, all of which solve the same problem and all of which fulfill the common unified basic idea, that the vacuum clamping device, in particular vacuum clamping plate, is designed in a special way.

According to the invention, all three aspects of the vacuum clamping device according to the invention provide a vacuum clamping device for clamping of workpieces, in particular for clamping of flat substrates.

Vacuum clamping devices as such are already known from the prior art. Therein the vacuum clamping in particular starts from the principle that outside and within a vacuum clamping device, which may be designed as a vacuum table or may be part of a vacuum table, initially the normal atmospheric air pressure is present, which is generally about 1 bar. The workpiece to be clamped is then applied to the vacuum clamping device. The air in the interior of the vacuum clamping device is sucked off with a vacuum device, for example a vacuum pump. Thereby a pressure difference between inside and outside is created, the boundary layer of which is the workpiece to be clamped. A vacuum is thus created between the workpiece and the vacuum clamping device. This is in particular a negative pressure, which is substantially, that means by a multiple, less than the ambient pressure, for example the atmospheric air pressure. The atmospheric air pressure now presses the workpiece against the vacuum clamping device. The upper side of the clamped workpiece can then be processed, possibly also the edge area of the workpiece, without the workpiece being able to slip.

In principle the invention is not limited to the clamping of specific workpieces. Preferably, the vacuum clamping device according to the invention is used for clamping of flat substrates. In principle, the invention is not limited to specific kinds of substrates. A substrate can generally be a support or carrier. For example, the substrate may be a wafer as described in the beginning, so that the vacuum clamping device is preferably used for clamping wafers.

If the substrate is a wafer, the vacuum clamping device is preferably a so-called chuck or a component of such a chuck. A chuck in particular is a mount, which is for example mounted at the processing table or which is such a processing table. The chuck picks up the waver for example by means of a generated vacuum.

The vacuum clamping device has a vacuum clamping plate, which has a number of suction openings distributed over its surface. Therein, the invention is not limited to a specific number of suction openings. The suitable number results in particular from the size and shape of the workpiece to be clamped and the magnitude of the holding forces to be generated. In any case, preferably more than two such suction openings are provided. The vacuum is generated or provided in the area of the workpiece to be clamped via the suction openings, wherein during generation of the vacuum via the suction openings the workpiece is sucked onto the vacuum clamping plate. In principle, the invention is not limited to a specific type of vacuum clamping plates. In a preferred embodiment, it may be provided that the suction openings are formed in a suction surface of the vacuum clamping plate. In this embodiment, the suction openings open into the suction surface and break through it. In the suction surface thus a number of suction openings are present, which may for example be drill holes and which are connected to device for generating vacuum, as will be described in more detail further below. In a different preferred embodiment, it is provided that the suction openings are in connection with a number of suction grooves, which are formed in the suction surface of the vacuum clamping plate. In this case, the vacuum as such is generated or provided via the suction grooves, wherein the suction grooves are also connected to the suction openings. In this exemplary embodiment, however, fewer suction openings may be provided.

In the following a first preferred exemplary embodiment how the vacuum clamping device may be designed according to the invention is described.

According to a first aspect of the invention, a vacuum clamping device for clamping workpieces, in particular for clamping flat substrates, is provided, with a vacuum clamping plate, which has a number of suction openings distributed over its surface, which are formed in a suction surface of the vacuum clamping plate or which are in connection with a number of suction grooves, which are formed in the suction surface of the vacuum clamping plate, wherein the vacuum clamping plate has two or more vacuum zones which are separated from each other and which can be switched individually, wherein each vacuum zone has respective suction openings and/or suction grooves. The vacuum clamping device is characterized in that the vacuum clamping device has two or more vacuum circuits which are independent from each other, in that each vacuum zone is assigned to one of the vacuum circuits or is part of one of the vacuum circuits, and in that each vacuum circuit is designed to generate a self-contained vacuum.

In addition to the features which have already been described above, it is provided in the vacuum clamping device according to the first invention aspect, that the vacuum clamping plate has two or more vacuum zones which are separated from each other and which are individually switchable, wherein each vacuum zone has respective suction openings and/or suction grooves with suction openings. As already mention above, such an embodiment of the vacuum clamping plate in two or more vacuum zones in principle is known from DE 10 2004 016 476 B4.

In contrast to the solution which is known from this publication, it is provided according to the invention, that the vacuum clamping device has two or more vacuum circuits which are independent from each other. A vacuum circuit basically consists of a series of different elements, which are necessary so that a vacuum can be generated or provided. The suction openings which are present in the suction surface of the vacuum clamping plate are in particular connected with vacuum channels or vacuum ducts. These vacuum channels or vacuum ducts are in particular connected via connection elements, for example corresponding valve elements with a device for generating vacuum, for example a vacuum pump. In principle, it can be stated that a vacuum circuit consists of a device for generating a vacuum, for example a vacuum pump, a negative pressure area and the vacuum clamping plate which is provided with the suction openings. The individual elements can be connected to each other via channels and ducts, for example via tubes, for example pneumatic tubes, possibly further using valves. If via the device for generating vacuum in the negative pressure area, the air pressure is reduced, a holding force is generated.

According to the invention, in contrast to the DE 10 2004 016 476 B4 it is now provided, that each vacuum zone is assigned to one of the vacuum circuits or is part of one of the vacuum circuits, and that each vacuum circuit is designed to generate a self-contained vacuum. With the known solution, in contrast, there is overall only one single vacuum circuit provided, to which all vacuum zones are assigned. This is because with the known solution it is to be achieved that the vacuum clamping plate should be adapted from its size as precisely as possible to the workpiece to the clamped, so that, where necessary, individual vacuum zones can be switched together to one single vacuum clamping plate.

With the solution according to the present invention a completely different route is now chosen. Herein each vacuum zone is assigned to an own vacuum circuit. With the solution according to the invention, there are at least two such vacuum circuits, which are independent from one another, and by means of which respectively independently a vacuum can be generated. A vacuum zone, which is assigned to a specific vacuum circuit, can therefore generate or provide a vacuum, which is independent from a vacuum which is generated or provided via a vacuum zone which is assigned to a different vacuum circuit.

With the present invention therefore not only at least two vacuum zones are provided which are structurally separated from each other, but which are in addition also functionally, with respect to the generation and the provision of a vacuum, separated from each other. Depending on the configuration and arrangement of the individual vacuum zones in the vacuum clamping plate it is therefore possible to generate or provide at defined locations very precisely and fast the respectively desired vacuum.

Some preferred exemplary embodiments for this will be explained in more detail in the further course of the description.

It may for example be provided that the vacuum clamping plate is divided into a larger number of two or more vacuum zones. In this embodiment, it may well be provided, that in each case several vacuum zones are assigned to a vacuum circuit. Nevertheless, at least two vacuum circuits are provided, so that each vacuum circuit has at least one vacuum zone assigned to it. In a different preferred embodiment it may be provided that each vacuum zone is assigned to its own vacuum circuit, so that by means of each of the vacuum zones a respective self-contained vacuum with respect to the other vacuum zones and independent of the other vacuum zones can be generated or provided.

Preferably, the individual vacuum zones are formed separately from each other and are separated by respective barriers or isolators. The individual vacuum zones are then subsequently joined together to the vacuum clamping plate. As each of the vacuum zones is assigned to its own vacuum circuit, they may be operated completely independent from each other. It is thus possible, as will be described in more detail below, that viewed over the entire vacuum clamping plate areas with respectively different vacuum can be provided, so that with the vacuum clamping device according to the invention areas with different magnitudes of holding forces may be formed.

In principle, the invention is not limited to a specific number of vacuum zones. In a preferred embodiment, the vacuum clamping plate is divided into two vacuum zones, wherein a first vacuum zone is several times larger than the second vacuum zone.

In a different preferred embodiment the vacuum clamping plate alternatively or in a further embodiment, is divided into two vacuum zones, wherein over a first vacuum zone a vacuum is generated or provided, which is larger, in particular several times larger than the vacuum which is generated or provided over the second vacuum zone.

The shape of the vacuum zones, in particular their size and/or contour as well as the vacuum which is generated or provided over the vacuum zone can be designed freely depending on the design.

In a preferred embodiment the vacuum clamping plate is of circular design, wherein at least one vacuum zone is designed as a circle sector or as circle segment. If the vacuum zones have different sizes, in particular, the smaller vacuum zone is such a circle sector or such a circle segment. A circle sector or also circle section is in particular the part of the area of a circle, which is delimited by the legs of an angle at center and the associated arc of the circle. A circle segment or also circle part is the part of the area of a circle, which is delimited by a chord and an arc of the circle which is associated to the chord. If a circle segment is provided, the circle is divided by the chord into two segments.

The vacuum clamping device according to this first aspect of the invention provides at least one additional vacuum zone which is operated via an own separate vacuum circuit and which can significantly improve the clamping of the workpiece. For example, it can be provided that it is desirable for an optimal clamping of the workpiece at the vacuum clamping device, if in different areas a different vacuum is generated or provided. This can be implemented with the present invention, which will be illustrated below with reference to a non-exclusive example from the field of wafer processing.

During the processing of wafers it is not uncommon to provide, that these are covered with a foil at least on one of their surfaces and at least temporarily, this foil usually being laminated onto the wafer. In some applications, this foil fulfills a protection function and in this respect is designed as a protection foil. In the further stage of the processing of the wafers, these protection foils then have to be removed again. This is generally done by means of a foil pull-off device provided for this purpose. The foil pull-off procedure, which can also be referred to as foil peeling procedure, generally is carried out in a way, that a specific pull-off foil or peeling foil is welded onto the protection foil which is to be pulled-off. Subsequently, the pull-off foil is pulled by means of the pull-off device, whereby the protection foil which is welded to the pull-off foil is also pulled off. In the area, where the pull-off foil is welded and in which the subsequent pull-off procedure starts, for which an initial pull-off force has to be applied, it can be advantageous if the holding force, with which the wafer is held by the vacuum clamping device is larger than in the remaining area. With the present invention it is now possible to provide an own vacuum zone with an own associated vacuum circuit in this pull-off area, so that in this area a different vacuum can be generated or provided than is the case in the remaining area.

According to a further aspect of the invention or in a preferred further development of the aforementioned first aspect, a vacuum clamping device for clamping a workpiece, in particular for clamping of flat substrates, is provided, with a vacuum clamping plate, which has a number of suction openings distributed over its surface, which are formed in the suction surface of the vacuum clamping plate or which are connected to a number of suction grooves, which are formed in a suction surface of the vacuum clamping plate, characterized in that the vacuum clamping plate is designed as an eccentric vacuum clamping plate.

Surprisingly it has been found, that the holding forces can be further increased by such an eccentric shape of the vacuum clamping plate.

An eccentric vacuum clamping plate is in particular characterized in that it has areas which do not have a common center point.

Preferably, it can be provided that the vacuum clamping plate has a circular shape and that the vacuum clamping plate has at least two areas, which do not have a common center point. This means that the circumference of the vacuum clamping plate at least partially describes different circular paths.

In a preferred embodiment, it is provided that the vacuum clamping plate has a circular shape, that the vacuum clamping plate has two or more vacuum zones which are separate from each other and which are individually switchable, wherein each vacuum zone has respective suction openings and/or suction grooves with suction openings and that the vacuum zones have circular shaped outer boundaries, which do not have a common center point.

When the vacuum clamping plate, for example, has two vacuum zones, wherein a first larger vacuum zone is provided and wherein a second, smaller vacuum zone is provided, which is for example designed, for example, as circle segment, the larger vacuum zone may for example be designed circular, while the second vacuum zone in the shape of a circle segment has an arc of a circle, which is eccentric thereto, which means that the boundaries of the two vacuum zones do not have a common center point.

According to a further aspect of the present invention or in a preferred further development of the two aforementioned aspects, a vacuum clamping device for clamping of workpieces, in particular for clamping of flat substrates, is provided, with a vacuum clamping plate, which has a number of suction openings distributed over its surface, which are formed in a suction surface of the vacuum clamping plate or which are in connection with a number of suction grooves, which are formed in a suction surface of the vacuum clamping plate, wherein the vacuum clamping plate is designed as vacuum plate ore wherein a vacuum plate is arranged in front of the vacuum clamping plate, wherein the vacuum plate has a first outer surface and a second outer surface opposed thereto and wherein the vacuum plate has a number of vacuum channels, which extend from the first outer surface to the second outer surface through the vacuum plate, characterized in that at least individual vacuum channels extend in a direction which deviates from the perpendicular orientation between the outer surfaces through the vacuum plate and/or that at least individual vacuum channels have a shape which deviates from a cylindrical shape.

In order to secure a workpiece against sliding, it is in particular reasonable to provide such a further vacuum plate between the workpiece and the vacuum clamping plate, which is preferably arranged between vacuum clamping plate and workpiece. Such a vacuum plate is to both be air-permeable, which is achieved by the vacuum channels, as well as have a high friction resistance, which can be achieved in particular by the material used for the vacuum plate.

In a preferred embodiment, it is provided that the further vacuum plate is fixed, for example glued, to the vacuum clamping plate,

The vacuum plate is penetrated by a number of vacuum channels. A vacuum channel therein in particular is a tubular connecting path between the two surfaces of the vacuum plate, wherein the ends of the connecting path lie in the surfaces and the connecting path thus opening into the surfaces. For this purpose, the vacuum plate has two outer surfaces, wherein the vacuum channels extend between the outer surfaces through the vacuum plate, such that the ends of the vacuum channels open into the outer surfaces and thus penetrate the vacuum plate. A vacuum plate with such vacuum channels is generally known in the state of the art and is for example mentioned in the further above mentioned DE 20 2013 100 632 U1. In this known solution it is however provided, that the vacuum channels extend perpendicular through the vacuum plate.

In contrast to the known solution is has now surprisingly been found that the holding forces can be increased in a targeted manner, if the vacuum channels are designed different in comparison to the known solution, namely in such a way, that at least individual vacuum channels extend through the vacuum plate between the outer surfaces in a direction deviating from the perpendicular orientation and/or that at least individual vacuum channels have a shape which deviates from a cylindrical shape. A cylinder basically is a body which is limited by two parallel planar surfaces, a base surface and a cover surface, and a lateral surface or cylinder surface, wherein the lateral surface is formed by parallel straight lines. A cylinder is in particular a tubular hollow body.

In principle, the invention is not limited to specific embodiments with respect to the orientation and/or shape of the vacuum channels. Preferably, at least individual vacuum channels can extend through the vacuum plate between the surfaces with an oblique path and/or at least individual vacuum channels can have a conical path. In a further embodiment it is also conceivable, that several connecting channels converge in a single point. The connecting channels serve for sucking air through them, so that the negative pressure or the vacuum can generate. By virtue of the special configuration of the vacuum channels and/or the specific orientation thereof, it is possible to adjust the holding forces as required for a secure holding of the workpiece.

In a preferred embodiment, at least individual vacuum channels in the vacuum plate are designed with respective different orientation and/or with respective different shape. This means, that the vacuum plate can be formed with respective vacuum channels in different orientations and/or shapes. For example, vacuum channels can be implemented as perpendicular or oblique drill holes with small diameter. A vacuum channel in a vacuum plate according to the invention can for example have a diameter of 50 μm. For flow optimization, drill holes with different geometries, for example cylindrical, conical or the like can be provided as vacuum channels.

The vacuum plate can be made of any material. While such vacuum plates have so far preferably consisted of a porous material, for example ceramics, due to the usage of the vacuum channels now also other materials are possible for the vacuum plate, so that it may for example also be made of metal, plastic or the like.

The connecting channels can be introduced into the vacuum plate in any manner, for example by means of laser drilling, laser ablation, etching or the like.

In a further embodiment it is preferably provided, that the vacuum clamping plate has a size and/or contour, which corresponds to the size and/or contour of the workpiece to be clamped, in particular of the flat substrate to be clamped.

Preferably, it can further be provided that the vacuum clamping plate at least partially has a projection in its peripheral area. Projection is in particular understood as an area, which extends over the vacuum clamping plate outwardly. When the workpiece is on the vacuum clamping plate, the projection thus extends over the edges of the clamped workpiece, for example of a wafer.

In the projection preferably a device for extraction of air is provided. For example, in the projection at least on extraction opening may be provided, via which the air can be extracted. Of course also several such extraction openings may be present. Air can thus be extracted at the edge of the clamped workpiece, for example of a wafer. If for example, a partial detachment of the workpiece from the vacuum clamping plate occurs, whereby a gap generates, where air at ambient pressure may enter, whereby the vacuum which is generated or provided via the vacuum clamping plate may collapse, this is avoided by the projection with the extraction opening as such air is immediately extracted and can thus not reach the gap which generates due to the partial detachment.

The present invention is not limited to specific embodiments for the design of the projection. For example, the projection may be arranged or formed circumferential in the peripheral area of the vacuum clamping plate. In a different embodiment, the projection can be arranged or formed in the shape of at least one protrusion section in the peripheral area of the vacuum clamping plate. Such a projection section can for example be a sort of a nose or flap. The projection sections are preferably arranged or formed in a distance to one another along the peripheral area of the vacuum clamping plate. If, as described before, extraction openings are provided, it is preferable that in each projection section at least one such extraction opening is formed.

### BRIEF DESCRIPTION OF THE DRAWINGS

The invention will now be described in more detail with reference to exemplary embodiments with reference to the enclosed drawings. Wherein:

FIG. 1 shows in schematic view an exemplary embodiment of a vacuum clamping plate according to the invention; and

FIG. 2 shows in schematic view a vacuum plate, which is arranged in front of the vacuum clamping plate.

### DETAILED DESCRIPTION OF THE PREFERRED EMBODIMENTS

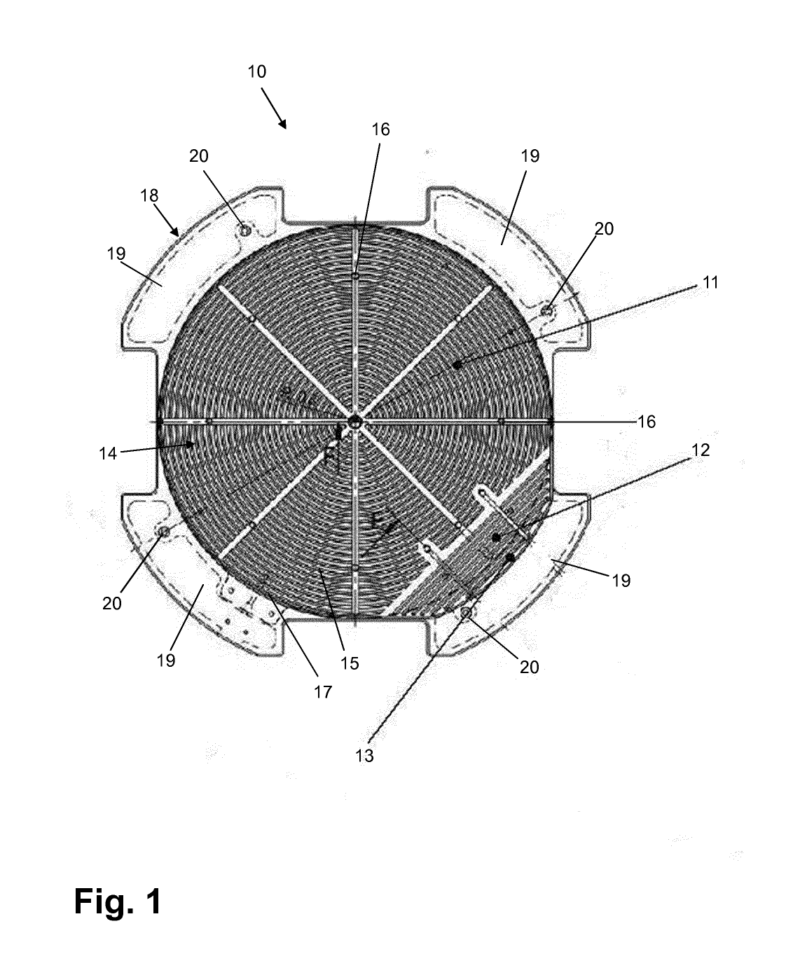

In FIG. 1 a vacuum clamping plate 10 for a vacuum clamping device is shown, wherein with the vacuum clamping device wafers are to be clamped. The vacuum clamping plate 10, which has a circular shape, has two vacuum zones 11, 12 which are separate from each other and are individually switchable, wherein a smaller vacuum zone 12, which is formed as a circle segment, in contrast to the first larger vacuum zone 11 has an eccentric shape 13. Each of the vacuum zones 11, 12 is assigned to its own vacuum circuit, so that in each of the two vacuum zones 11, 12, a self-contained, independent vacuum can be generated. The generation of the vacuum is performed such that the vacuum clamping plate 10 all together has a suction surface 14, on which suction grooves 15 are located. Furthermore, a series of suction openings 16 is provided, which are in connection with the suction grooves 15.

If now a wafer (not shown) is clamped onto the vacuum clamping plate, it is first laid onto the vacuum clamping plate. Subsequently air is sucked in via the suction grooves 15 and the suction openings 16, which is performed via a device for generating a vacuum, for example a vacuum pump, which is not shown. For this purpose, the vacuum pump is connected via appropriate negative pressure devices, which may comprise for example channels, ducts, valves and the like, to the suction openings 16.

As a result of the fact that the vacuum clamping plate 10 has two different vacuum circuits which are separate from each other, each having a vacuum zone 11 and a vacuum zone 12 and of the fact that the one vacuum zone 12 has an eccentric shape 13, the holding forces for the wafer can be increased, whereby the increase of the holding forces can preferably be effected in a targeted manner. If for example a vacuum which is larger in comparison to the larger vacuum zone 11, is to be generated or provided with the smaller vacuum zone, a larger holding force can be generated very precisely and targeted in the area of the vacuum zone 12, which is advantageous in some wafer processing operations.

A projection 18 in the shape of four projection sections 19 extends over the peripheral area 17 of the vacuum clamping plate 10. In each projection section 19 an extraction opening 20 for air is provided. Thereby air can be extracted in the peripheral area 17 of the vacuum clamping plate 10. This is for example advantageous, if the wafer partially detaches from the vacuum clamping plate 10. No air can then enter into the gap which is formed thereby anymore, so that a collaps of the vacuum can be avoided.

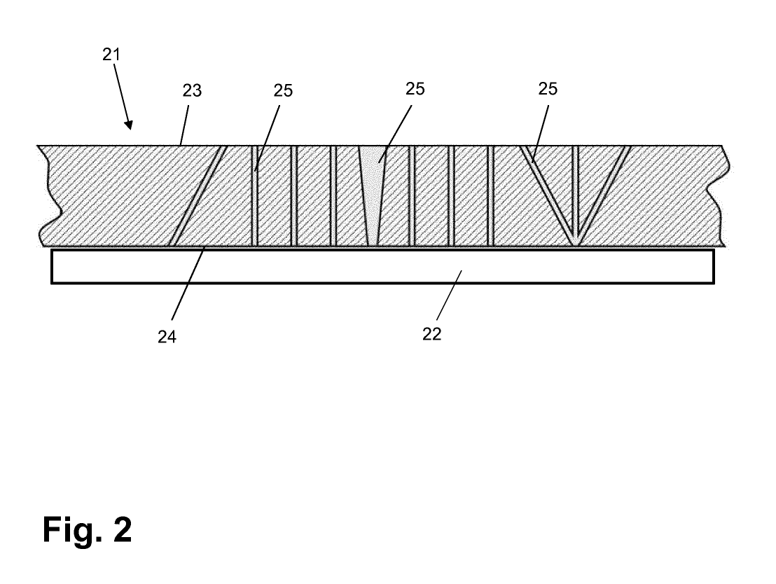

On the vacuum clamping plate 10 a further vacuum plate 21 can be fixed, for example glued, which is shown in FIG. 2. In order to avoid a sliding of the wafer 22, it is reasonable to provide such a vacuum plate 21 between the wafer 22 and the vacuum clamping plate 10. The vacuum plate 21 has a first outer surface 23 and a second outer surface 24, wherein a number of vacuum channels 25 extend from the outer surfaces 23, 24 through the vacuum plate 21. Perpendicular or oblique drill holes of small diameter may be provided as vacuum channels 25. For further optimizing the flow, the vacuum channels 25 can have different geometries, for example a cylindrical geometry, a conical geometry and the like.

### REFERENCE NUMBERS

10 vacuum clamping plate
11 vacuum zone
12vacuum zone
13 eccentric shape
14suction surface
15 suction groove
16 suction opening
17peripheral area
18 projection
19 projection section
20 extraction opening
21 vacuum plate
22 wafer
23outer surface
24 outer surface
25 vacuum channel

1. Vacuum clamping device for clamping of workpieces, in particular for clamping of flat substrates, with a vacuum clamping plate, which has a number of suction openings which are distributed over its surface and which are formed in a suction surface of the vacuum clamping plate or which are in connection to a number of suction grooves which are formed in the suction surface of the vacuum clamping plate, wherein the vacuum clamping plate has two or more vacuum zones which are separate from each other and are individually switchable, wherein each vacuum zone has corresponding suction openings and/or suction grooves with suction openings, characterized in that the vacuum clamping device has two or more separate vacuum circuits which are independent from each other, that each vacuum zone is assigned to one of the vacuum circuits or is part of one of the vacuum circuits and that each vacuum circuit is designed for generating a self-contained vacuum.

2. Vacuum clamping device according to claim 1, characterized in that the vacuum clamping plate is divided into two vacuum zones and that a first vacuum zone in terms of area is several times larger than the second vacuum zone.

3. Vacuum clamping device according to claim 1, characterized in that the vacuum clamping plate is divided into two vacuum zones and that a vacuum is generated or provided via a first vacuum zone which is larger, in particular several times larger, than the vacuum which is generated or provided via the second vacuum zone.

4. Vacuum clamping device according to claim 1, characterized in that the vacuum clamping plate has a circular shape and that at least one vacuum zone is formed as a circle sector or circle segment.

5. Vacuum clamping device for clamping of workpieces, in particular for clamping of flat substrates, with a vacuum clamping plate, which has a number of suction openings which are distributed over its surface and which are formed in a suction surface of the vacuum clamping plate or which are in connection to a number of suction grooves which are formed in the suction surface of the vacuum clamping plate, in particular vacuum clamping device according to claim 1, characterized in that the vacuum clamping plate is formed as an eccentric vacuum clamping plate.

6. Vacuum clamping device according to claim 5, characterized in that the vacuum clamping plate has a circular shape and that the vacuum clamping plate has at least two areas, which have no common center point.

7. Vacuum clamping plate according to claim 5, characterized in that the vacuum clamping plate has a circular shape, that the vacuum clamping plate has two or more vacuum zones which are separate from each other and are individually switchable, wherein each vacuum zone has corresponding suction openings and/or suction grooves with suction openings and that the vacuum zones have outer circular boundaries which have no common center point.

8. Vacuum clamping device for clamping of workpieces, in particular for clamping of flat substrates, with a vacuum clamping plate, which has a number of suction openings which are distributed over its surface and which are formed in a suction surface of the vacuum clamping plate or which are in connection to a number of suction grooves which are formed in the suction surface of the vacuum clamping plate, in particular vacuum clamping device according to claim 1, wherein the vacuum clamping plate is formed as a vacuum plate or wherein in front of the vacuum clamping plate a vacuum plate is arranged, wherein the vacuum plate has a first outer surface and a second outer surface which is opposed thereto and wherein the vacuum plate has a number of vacuum channels, which extend from the first outer surface to the second outer surface through the vacuum plate, characterized in that at least individual vacuum channels extend in an orientation which deviates from the perpendicular orientation between the outer surfaces through the vacuum plate and/or that at least individual vacuum channels have a shape which deviates from a cylindrical shape.

9. Vacuum clamping device according to claim 8, characterized in that at least individual vacuum channels extend with an oblique path between the outer surfaces through the vacuum plate and/or that at least individual vacuum channels have a conical path.

10. Vacuum clamping device according to claim 8, characterized in that in the vacuum plate at least individual vacuum channels are formed with respective different orientation and/or with respective different shape.

11. Vacuum clamping device according to claim 1, characterized in that the vacuum clamping plate has a size and/or contour which corresponds to the size and/or contour of the workpiece to be clamped, in particular of the flat substrate to be clamped.

12. Vacuum clamping device according to claim 1, characterized in that the vacuum clamping plate in its peripheral area at least partially has a projection.

13. Vacuum clamping device according to claim 12, characterized in that the projection is arranged or formed circumferentially in the peripheral area of the vacuum clamping plate or that the projection is arranged or formed in the shape of a projection section in the peripheral area of the vacuum clamping plate.

14. Vacuum clamping device according to claim 1, characterized in that it is used for clamping wafers.
